(19) United States
(12) Patent Application Publication
(10) Pub. No.: US 2011/0205723 A1
(43) Pub. Date: Aug. 25, 2011

(54) DISPLAY DEVICE

(76) Inventor: Man-Yong Chol, Seoul (KR)

(21) Appl. No.: 13/125,005

(22) PCT Filed: Apr. 24, 2009
(86) PCT No.: PCT/KR2009/002161

§ 371 Date: Apr. 19, 2011

(30) Foreign Application Priority Data
Oct. 20, 2008 (KR) 10-2008-0102612

(51) Int. Cl. H05K 7/02

(52) U.S. Cl. 361/807

(57) ABSTRACT

The present invention provides a display device. The display device includes a front panel that forms a front appearance and through which an image is transmitted; a supporter that is fixed to the rear surface of the front panel; a back cover that forms a rear appearance and is supported by the supporter in a state where it contacts the supporter; and a display module that is received in a space formed by the front panel and the back cover, wherein the supporter electrically connects the front panel to the back cover.

### TECHNICAL FIELD

The present invention relates to a display device.

### BACKGROUND ART

Generally, a display device is a device that displays an image. A plurality of flat panel display devices of which figures can be formed in a two-dimensional flat panel have been recently released. Such a flat panel display has advantages in view of small volume occupied in an indoor space, light weight, and convenience in handling thereof, so that it has been greatly spotlighted by consumers.

The display device has a plasma display module, making it possible to allow an image to be displayed. The plasma display module is a module that uses a feature that when ultraviolet rays generated by a gas discharge excites a phosphor, a visible ray is generated from the phosphor.

In the case of a general display device, the plasma display module is protected by a front cabinet and a rear cabinet. In other words, the front cabinet serves to form a front appearance of the display device simultaneously with covering the plasma display module.

### DISCLOSURE OF INVENTION

### Technical Problem

An object of the present invention is to provide a display device that reduces the number of components and reduces manufacturing costs.

Another object of the present invention is to provide a display device that makes a front appearance clear and reduces a thickness thereof.

### Technical Solution

To achieve the above objects, according to one aspect of the present invention, there is provided a display device, including: a front panel that forms a front appearance and through which an image is transmitted; a supporter that is fixed to the rear surface of the front panel; a back cover that forms a rear appearance and is supported by the supporter in a state where it contacts the supporter; and a display module that is received in a space formed by the front panel and the back cover, wherein the supporter electrically connects the front panel to the back cover.

According to another aspect of the present invention, there is provided a display device, including: a front panel that forms a front appearance and through which an image is transmitted; a display module that provides the image; a supporter that is made of conductive material and is fixed to the rear surface of the front panel; and a back cover that is grounded with the supporter to cover the display module.

### ADVANTAGEOUS EFFECTS

With the present embodiment as described above, the back cover is coupled to the supporter that includes the ground part, in a state being electrically connected, the ground function for shielding the electromagnetic wave and the function to fix the cover can be performed simultaneously by the supporter, and the structure of the display device can be simplified. Therefore, the thickness of the display device is reduced, having an advantage that the display device is entirely slimmed.

Also, the back cover and the plasma display module are fixed to the supporter, having advantages that the number of components of the display device is reduced and the manufacturing costs and process is reduced.

Also, the front panel made of glass material forms the entire front appearance of the display device, having advantages that the front appearance of the display device becomes clear and a screen to be displayed thereon seems to be large.

### BRIEF DESCRIPTION OF DRAWINGS

The above and other objects, features and advantages of the present invention will become apparent from the following description of preferred embodiments given in conjunction with the accompanying drawings, in which:

FIG. 1 is a front perspective view of a display device according to a first embodiment of the present invention;

FIG. 2 is a rear perspective view of the display device according to the first embodiment of the present invention;

FIG. 3 is an exploded perspective view of the display view according to the first embodiment of the present invention;

FIG. 4 is a cross-sectional view taken along line B-B of FIG. 3;

FIG. 5 is a cross-sectional view taken along line A-A of FIG. 1;

FIG. 6 is a cross-sectional view taken along line A-A of FIG. 1 according to a second embodiment of the present invention; and

FIG. 7 is a cross-sectional view taken along line A-A of FIG. 1 according to a third embodiment of the present invention.

### MODE FOR THE INVENTION

Hereinafter, the present invention will be described in detail with reference to the accompanying drawings.

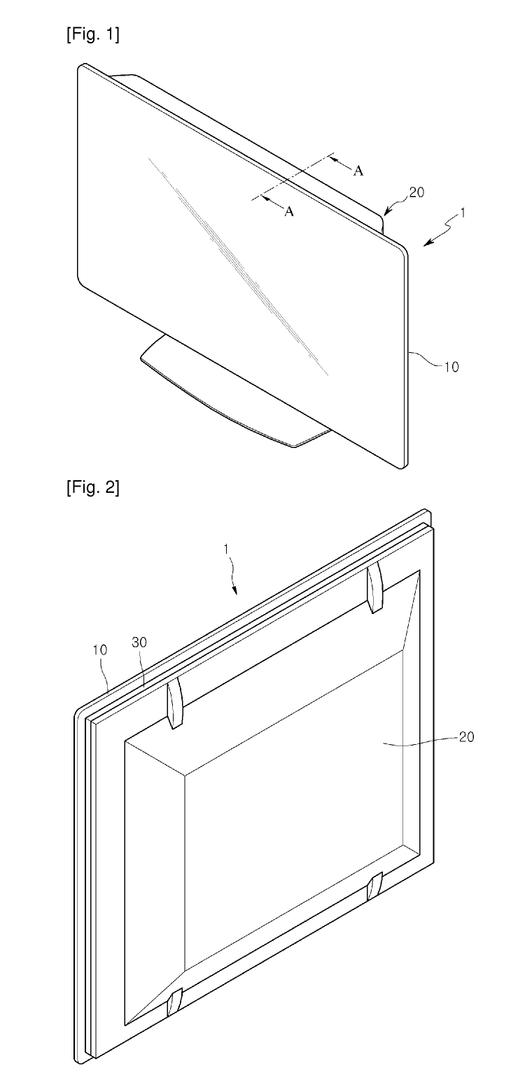

FIG. 1 is a front perspective view of a display device according to a first embodiment of the present invention, and FIG. 2 is a rear perspective view of the display device according to the first embodiment of the present invention.

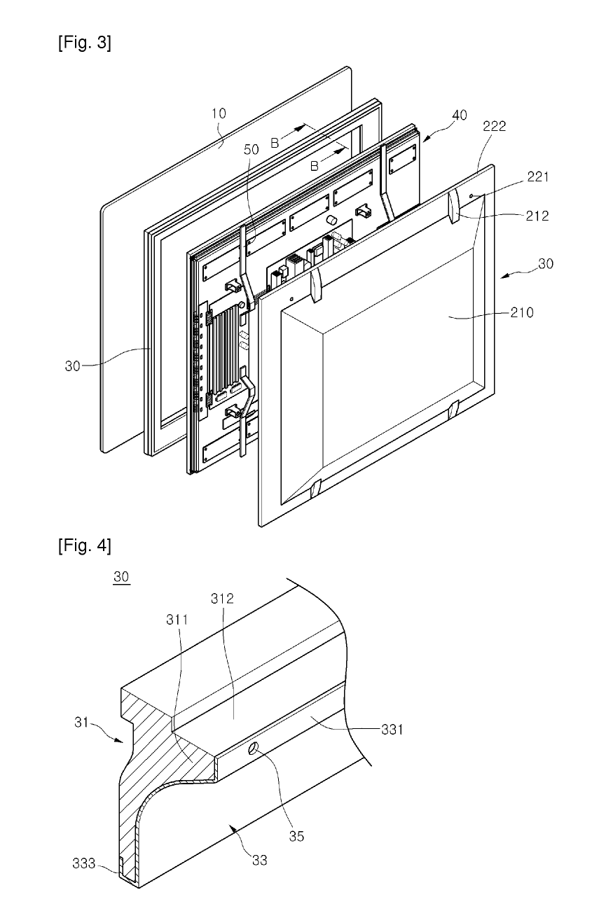

Referring to FIGS. 1 and 2, the display device 1 according to the present embodiment includes a front panel 10 that forms a front appearance and through which an image is transmitted, a back cover 20 that forms a rear appearance and shields electromagnetic waves, and a supporter 30 that supports the back cover 20 to be fixed to the front panel 10. And, a plasma display module (see 40 of FIG. 3) is provided between the front panel 10 and the back cover 20.

In the present embodiment, the front panel 10, the back cover 20, and the supporter 30 form the entire appearance of the display device 1.

In other words, in the present invention, a separate front cabinet that protects the plasma display module 40 is removed and the front panel 10 forms the entire appearance of the front surface.

At this time, the horizontal length and the vertical length of the front panel 10 are formed to be equivalent to or larger than the horizontal length and the vertical length of the back cover 20.

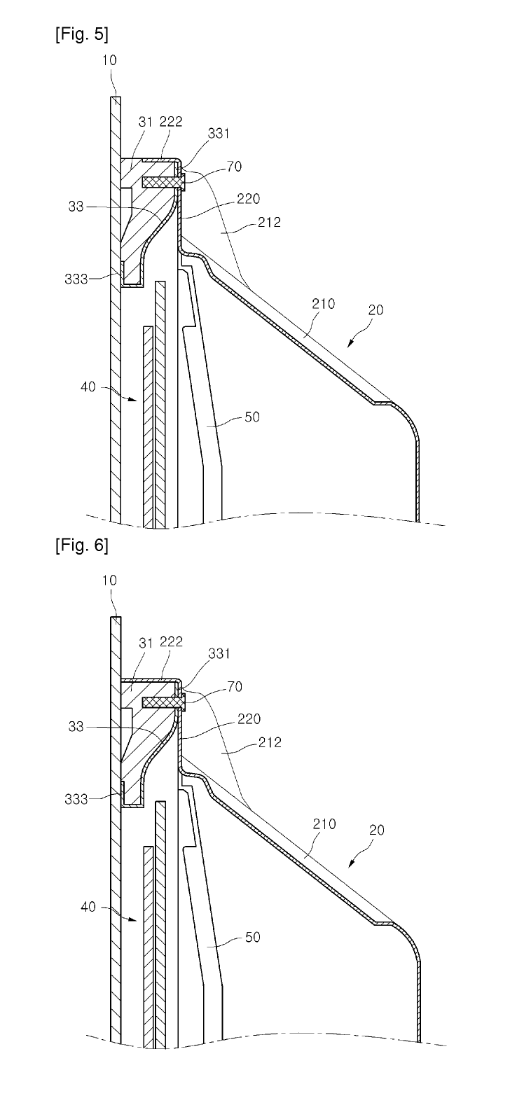

FIG. 3 is an exploded perspective view of the display view according to the first embodiment of the present invention, FIG. 4 is a cross-sectional view taken along line B-B of FIG. 3, and FIG. 5 is a cross-sectional view taken along line A-A of FIG. 1.

Referring to FIGS. 3 to 5, the plasma display module 40 is provided between the front panel 10 and the back cover 20. The plasma display module 40 is coupled to the supporter 30 fixed to the rear surface of the front panel 10.

The front panel 10 is made of glass material and is formed to be transparent so that an image is transmitted therethrough. And, the front panel 10 may be made of tempered glass in order to satisfy the strength condition according to the trend to make the front panel 10 large. However, the front panel 10 is not limited to the material of the proposed embodiment but may be made of various materials such as transparent plastic material. In other words, any kinds of materials that are transparent and satisfy the strength of predetermined level or higher may be used and this may belong to the scope of the idea of the present embodiment.

Also, for example, a plurality of layers, such as an anti-reflection coating, an optical property layer, an EMI shielding layer, and a near infrared (hereinafter, referred to as NIR) shielding layer, etc., may be provided on the front panel 10.

The supporter 30 may be provided with four members that form the appearance of the supporter 30 in an integrated form or may be coupled with a plurality of separate members that are provided separately. ( [symbol] ) The supporter 30 may be fixed to the rear surface of the front panel 10 using an adhesive member (not show) or adhesives, wherein the adhesive material may use, for example, a both faces tape. In the process to be coupled to the rear surface of the front panel 10, the supporter 30 is positioned on the inner side by a predetermined distance towards the center of the front panel 10 to be coupled to the rear surface of the front panel 10. In other words, in a state where the supporter 30 is coupled to the rear surface of the front panel 10, the front panel 10 is provided in a state where the front panel 10 is further elongated by a predetermined size from the region where it is overlapped with the supporter 30 towards the outside.

The supporter 30 includes a supporter body 31 that forms the appearance of the supporter 30 and a ground part 33 that grounds the back cover 20 with the front panel 10.

The supporter body 31 may be made of synthetic resins by way of example. And, the supporter body 31 includes a coupling part 31 that is coupled with the back cover 20. And, a seating surface 312 on which the back cover 20 is seated is formed on the coupling part 311.

The ground part 33 may be made of conductive member, for example, aluminum or copper material. For example, the ground part 33 may be formed by hot-stamping thin conductive material on the other surface of the supporter body 31 or ejecting metal material in a dust state onto the surface of the supporter body 311.

And, the ground part 33 includes first and second ground parts 331 and 332.

The first ground part 331 is grounded with the back cover 20, and the second ground part 332 is grounded with the rear surface of the front panel 10. Therefore, in a state where the supporter body 31 is fixed to the rear surface of the front panel 10, the second part 331 contacts the rear surface of the front panel 10 to allow the front panel 10, the ground part 33, and the back cover 20 to be grounded with each other.

Meanwhile, an engaging hole 35 that penetrates through the first ground part 331 and the coupling part 311 is formed on the supporter 30. And, an engaging member 70 that penetrates through the back cover 20 is coupled to the engaging hole 35.

Meanwhile, the plasma display module 40 is coupled to the supporter 30 by a connecting member 50. One side of the connecting member 50 is coupled to the plasma display module 40, and the other side of the connecting member 50 is coupled to the supporter 30.

In a state where the plasma display module 40 is coupled to the supporter 30, the supporter 30 is positioned on the outsides of top surface, bottom surface and both left and right surfaces of the module 40.

Meanwhile, the back cover 20 is made of metal material and is coupled to the supporter 30, in a ground state, that is, in a state where the back cover 20 is electrically coupled.

Differently therefrom, the back cover 20 may include, for example, a body of plastic material and a conductive layer that conductive material (for example, aluminum) is coated or attached on the inner surface of the body, making it possible to be grounded with the ground part 33. In other words, the idea of the present embodiment includes all structures where the back cover 20 can be grounded with the ground part 33.

The back cover 20 includes a body part 210 that forms an appearance and an elongated part 220 that is elongated from the body part 210 to be grounded with the ground part 33.

The elongated part 220 is elongated from four edges of the body part 210 to the outside and at least portions of the elongated part are positioned to be opposite to the rear surface of the front panel 10.

At this time, the four edges of the elongated part 220 are formed to be smaller than or equivalent to the four edges of the front panel 10. Therefore, in a state where the back cover 20 is coupled to the front panel 10, only the front panel 10 is seen from the front of the display device 1.

And, the back cover 20 may be engaged with the supporter 30 fixed to the rear surface of the front panel 10 by the engaging member 70. An engaging hole 221 that allows the engaging hole 70 to be engaged is formed on the elongated part 220. The engaging member penetrates through the engaging hole 221 of the elongated part 220 in the rear of the back cover 20 to be engaged with the engaging hole 35 of the supporter 30.

In a state where the back cover 20 is engaged with the supporter 30, the elongated part 220 contacts the first ground part 331 of the supporter 30. Therefore, in a state where the front panel 10, the back cover 20, and the supporter 30 are grounded with each other, an electromagnetic wave shielding space is formed therein. And, the display module 40 is provided in the electromagnetic wave shielding space so that the emission of electromagnetic wave generated from the display module 40 to the outside of the display device 1 can be prevented.

Meanwhile, in order to prevent the interference with the connecting member 50 in a state where the back cover 20 contacts the front panel 10, a receiving part 212 that receives the connecting member 50 is formed on the body part 210. The receiving part 212 is formed as a portion of the body part 210 is protruded backwards.

And, an edge part 222 that is elongated from the four edges of the elongated part 220 of the back cover 20 to the front panel 10 side is formed. The edge part 222 is seated on the seating surface 312 of the supporter 30 during the coupling process of the back cover 20 to the supporter 30.

With the present embodiment as described above, the back cover 20 is coupled to the supporter 30 that includes the ground part 33, in a state being electrically connected, the ground function for shielding the electromagnetic wave and the function to fix the cover 20 are performed simultaneously by the supporter 30. Therefore, the structure of the display device 1 is simplified and the thickness of the display device 1 is reduced, having an advantage that the display device 1 is entirely slimmed.

Also, the back cover 20 and the plasma display module 40 are fixed to the supporter 30, having advantages that the number of components of the display device is reduced and the manufacturing costs and process is reduced.

Also, the front panel 10 made of glass material forms the entire front appearance of the display device 1, having advantages that the front appearance of the display device becomes clear and a screen to be displayed thereon seems to be large.

FIG. 6 is a cross-sectional view taken along line A-A of FIG. 1 according to a second embodiment of the present invention.

The present embodiment is the same as the first embodiment, except for the characteristics that the edge part 222 of the back cover 20 is elongated up to the front panel 10 side. Therefore, hereinafter, only the characteristic portion of the present embodiment will be described.

Referring to FIG. 6, the edge part 221 of the back cover 20 in the present embodiment contacts the front panel 10 in a state where the back cover 20 is coupled to the supporter 30.

Therefore, in the state where the back cover 20 is coupled to the supporter 30, the top, bottom, lateral, and rear of the supporter 30 are positioned in the inner side of the back cover 20. In other words, the supporter 30 is prevented from being exposed to the external by the back cover 20.

With the present embodiment as described above, the appearance of the display device 1 is formed only by the front panel 10 and the back cover 20, having an advantage that the entire appearance of the display device 1 becomes good.

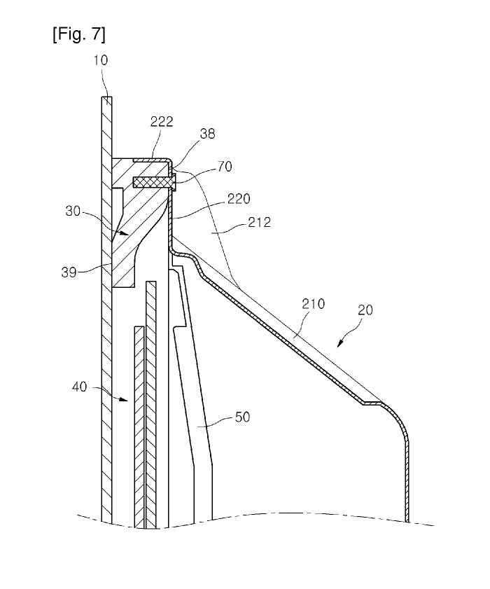

FIG. 7 is a cross-sectional view taken along line A-A of FIG. 1 according to a third embodiment of the present invention.

The present embodiment is the same as the first embodiment, except for the characteristics that the supporter 30 is made of a single conductive material. Therefore, hereinafter, only the characteristic portion of the present embodiment will be described.

Referring to FIG. 7, the supporter 30 of the present embodiment may be formed of a single conductive material, for example, aluminum or copper. And, the supporter 30 includes a first ground part 38 contacts the back cover 20 and a second ground part 39 that contacts the front panel 10. Therefore, if the back cover 20 is grounded with the first ground part 38, the back cover 20 is grounded with the front panel 10 by the supporter 30.

With the present embodiment as described above, the supporter 30 is made of the single conductive material to electrically connect the back cover 20 to the front panel 10, having advantages that the structure of the display device 1 is simplified and the manufacturing process of the supporter 30 is simplified.

1. A display device, comprising:
a front panel that forms a front appearance and through which an image is transmitted;
a supporter that is fixed to the rear surface of the front panel;
a back cover that forms a rear appearance and is supported by the supporter in a state where it contacts the supporter; and
a display module that is received in a space formed by the front panel and the back cover,
wherein the supporter electrically connects the front panel to the back cover.

2. The display device according to claim 1, wherein the supporter includes a supporter body that is fixed to the rear surface of the front panel; and a ground part that is made of conductive material and is formed on the surface of the supporter body.

3. The display device according to claim 2, wherein the ground part is coated on the surface of the supporter body.

4. The display device according to claim 2, wherein the ground part includes a first ground part that is grounded with the back cover; and a second ground part that is grounded with the rear surface of the front panel.

5. The display device according to claim 2, wherein the supporter body includes a coupling part that is coupled with the back cover; and a seating surface that allows at least portions of the back cover to be seated.

6. The display device according to claim 1, wherein the supporter is made of a single conductive material.

7. The display device according to claim 1, wherein the back cover includes a body that forms the appearance of the back cover; and an elongated part that is elongated from the body part to the outside and is grounded with the supporter.

8. The display device according to claim 7, wherein the back cover surrounds the supporter in a state where it contacts the supporter to prevent the supporter from being exposed to the external.

9. The display device according to claim 1, wherein at least portions of the back cover is made of conductive material.

10. The display device according to claim 1, further comprising:
a connecting member that connects the display module to the supporter.

11. The display device according to claim 1, wherein the display module is coupled to the supporter so that its position is fixed.

12. The display device according to claim 1, wherein the supporter is positioned on the outsides of the top surface, bottom surface, and both left and right surfaces of the display module to prevent the display module from being exposed to the external.

13. The display device according to claim 1, wherein in a state where the supporter is fixed to the rear surface of the front panel, the front panel is elongated from the region where it is overlapped with the supporter to the outside by a predetermined size.

14. The display device according to claim 1, wherein the supporter is adhered and fixed to the rear surface of the front panel.

15. A display device, comprising:
a front panel that forms a front appearance and through which an image is transmitted;
a display module that provides the image;
a supporter that is made of conductive material and is fixed to the rear surface of the front panel; and
a back cover that is grounded with the supporter to cover the display module.

16. The display device according to claim 15, wherein a shielding space that is shielded electrically from the external by the front panel, the supporter, and the back cover is formed and the display module is provide in the shielding space.

17. The display device according to claim 15, wherein the back cover and the display module are fixed to the supporter.

18. The display device according to claim 15, wherein the horizontal length or the vertical length of the front panel is formed to be equivalent to or larger than the horizontal length or the vertical length of the back cover.

19. The display device according to claim 15, wherein at least portions of the supporter are formed of conductive material.

20. The display device according to claim 15, wherein the supporter includes a first ground part that is provided on one surface of the supporter to contact the back cover; and a second ground part that is provided on the other surface of the supporter to contact the front panel.
